(19) United States
(12) Patent Application Publication
(10) Pub. No.: US 2014/0225271 A1
(43) Pub. Date: Aug. 14, 2014

(54) PANELIZED PACKAGING WITH TRANSFERRED DIELECTRIC

(71) Applicant: DECA Technologies Inc., Tempe, AZ (US)

(72) Inventor: Christopher M. Scanlan, Chandler, AZ (US)

(73) Assignee: DECA Technologies Inc., Tempe, AZ (US)

(21) Appl. No.: 14/261,265

(22) Filed: Apr. 24, 2014

Related U.S. Application Data
(62) Division of application No. 12/985,212, filed on Jan. 5, 2011.
(60) Provisional application No. 61/305,122, filed on Feb. 16, 2010.

(51) Int. Cl. H01L 23/29; H01L 23/528

(52) U.S. Cl. CPC H01L 23/293; H01L 23/528
USPC 257/773; 257/793

(57) ABSTRACT

Panelized packaging is described in which a plurality of die units are placed on a dielectric film. The dielectric film is then cured to lock the plurality of die unit in place, which are then encapsulated. The cured dielectric film is then patterned utilizing a mask-less pattering technique.

### RELATED APPLICATIONS

This application is a divisional application of U.S. patent application Ser. No. 12/985,212, titled “Panelized Packaging With Transferred Dielectric,” filed Jan. 5, 2011, and also claims the benefit of U.S. Provisional Application No. 61/305,122, filed Feb. 16, 2010, the disclosures of which are incorporated herein by this reference.

### TECHNICAL FIELD

Embodiments of the present invention relate to the field of panelized packaging.

### BACKGROUND

A common implementation of panelized packaging gaining acceptance in industry is fan-out wafer level packaging (WLP) in which multiple die units are placed face down on a temporary tape carrier. The multiple die units and temporary tape carrier are overmolded with a molding compound using a compression molding process. After molding the tape carrier is removed, leaving the active surface of the multiple die units exposed in a structure commonly refereed to as a reconstituted wafer, Subsequently, a wafer level chip scale package (WLCSP) build-up structure is formed on top of the reconstituted wafer. Bail grid array (BGA) bails are attached to the reconstituted wafer and then the reconstituted wafer is saw singulated to form individual packages. It has been observed that the die unit placement and overmolding processes may cause displacement and/or rotation of the die units, resulting in defective packages and yield loss.

### BRIEF DESCRIPTION OF THE DRAWINGS

FIGS. 1A-1N illustrate a method of forming a fan-out WLP, in accordance with an embodiment of the present invention.

FIGS. 2A-2L illustrated method of forming a fan-out WLP, in accordance with an embodiment of the present invention.

### DETAILED DESCRIPTION

Embodiments of the present invention disclose methods and structures to improve panelized packaging, such as fan-out WLCSP. In the following description, specific embodiments are described with regard to single die applications. Embodiments of the present invention may also be useful in multi-die modules or some combination of die and passive components (such as a capacitor, inductor or resistor) and/or other components (such as an optical element, connector or other electronic component) within modules.

In the following description, numerous specific details are set forth, such as specific configurations, compositions, and processes, etc., in order to provide a thorough understanding of the present invention. In other instances, well-known processes and manufacturing techniques have not been described in particular detail in order to not unnecessarily obscure the present invention. Furthermore, it is to be understood that the various embodiments shown in the Figures are illustrative representations and are not necessarily drawn to scale.

The terms “over”, “between” and “on” as used herein refer to a relative position of one layer with respect o other layers. One layer deposited or disposed over or under another layer may be directly in contact with the other layer or may have one or more intervening layers. One layer deposited or disposed between layers may be directly in contact with the layers or may have one or more intervening layers. In contrast, a first layer “on” a second layer is in contact with that second layer.

In an embodiment, a panelized package is created by placing a plurality of die units face down on a dielectric film, which may be laminated on a temporary carrier substrate. The dielectric film is then cured to lock the plurality of die units in place, rendering the dielectric film non-photoimageable. During cure changes occur at the molecular level in the dielectric film material where the mechanical properties of the dielectric substantially fully develop and the die units permanently adhere to the resultant rigid dielectric film. Depending upon the particular materials employed curing may be associated with cross-linking. The plurality of die units are then encapsulated on the dielectric film. In an embodiment, encapsulation may be achieved by an overmolding process such as compression molding. In an embodiment, encapsulation may be performed by a lamination process such as vacuum lamination. Because the plurality of die units have been locked into place prior to encapsulation, displacement and/or rotation of the individual die units may be reduced during encapsulation where displacement and/or rotation of the individual die units can be problematic due to pressures exerted on the individual die units. The temporary carrier substrate may then be released from the dielectric film. A wafer level chip scale package (WLCSP) build-up structure may then be formed including the rigid, cured, continuous dielectric film which may be patterned utilizing a mask-less patterning technique.

It has been observed that die unit placement and encapsulation processes of conventional processing technologies may cause displacement and/or rotation of the orientation of any of the plurality of die units on a temporary tape carrier. This may be attributed to the die units not being rigidly attached to the temporary tape carrier, deformation of the tape carrier, as well as shrinkage of the encapsulant during curing of the encapsulant. The impact of conventional methods utilizing a temporary tape carrier is either yield loss due to misalignment of first vias to the die unit bond pads, or the addition of some intermediate form of bond pad re-routing in native wafer form (prior to panelization) to make large bond pads as targets to ensure the first vias make connection despite die unit movement. As a result, conventional processing technology requires that bond pads on the die units be larger than necessary to avoid yield loss from the panel, thereby reducing the application space for WLP technology.

In accordance with embodiments of the present invention, a continuous dielectric film, such as a laminated epoxy film, can replace both the temporary, sacrificial tape and the first dielectric layer in the build-up structure. This has the potential to reduce cost and process steps. Locking the plurality of die units in place on the continuous dielectric film prior to encapsulation may reduce displacement and/or rotation of the orientation of the individual die units within a panel or reticulated wafer thereby eliminating or reducing package assembly yield loss caused by misalignment of the die units during panetization and allowing for a smaller bond pad opening on the die units. Epoxy is a suitable material from which to form the dielectric film because it may be cured to lock the plurality of die units in place, and also because a similar epoxy can be utilized as an overmolding or lamination encapsulant. Other materials having suitable adhesive properties for locking the plurality of die units in place are also contemplated with embodiments of the invention such as, but not limited to, polyimide and silicone.

In another aspect, embodiments of the present invention disclose methods of panelized packaging which may utilize lamination techniques. For example, lamination may provide for uniform thickness of a laminated dielectric film across a temporary carrier substrate. A laminated dielectric film may also be subsequently removable from the temporary carrier substrate. In a particular embodiment, a B-stage cured dielectric film material such as a B-stage cured epoxy material is laminated onto the temporary carrier substrate. A B-stage cured material is commonly one in which a limited reaction between a resin and hardener has taken place so that the material is in a solid state with partially developed network (semi-cured). In this state, the B-stage cured material may still be fusible. The B-stage cured material may be final cured by additional exposure to heat and/or radiation, where the network may become fully developed (e.g. cross-linked), rigid and non-photoimageable. Final curing may also be accompanied by moderate flow.

Such a B-stage cured dielectric film material may retain adhesive properties (tack) that assist with retaining the location of the plurality of die units during placement of the plurality of die units on the dielectric film, and experiences only moderate flow during final cure to lock the plurality of die units in place. As a result, the laminated dielectric film formed from a B-stage cured material may exhibit desirable planarity after across the panel after cure. Additionally, as a result of the planarity of the dielectric film surface upon which the plurality of die units are placed, a discontinuity does not exist in the dielectric film adjacent the edges of the die units. Accordingly, the active surfaces of the die units and the dielectric film surface upon which the due units are placed are both in the same plane which may be beneficial for device reliability metrics such as delamination during moisture sensitivity testing, or mounting to a motherboard or other product.

Lamination may also be utilized to encapsulate the plurality of die units on the dielectric film. For example, vacuum encapsulation can be utilized with a B-stage cured epoxy of similar or identical composition as the dielectric film. As a result, the physical properties such as coefficient of thermal expansion (CTE), hardness and elastic modulus or weight percent of filler in the laminated encapsulant layer and the dielectric film can be closely matched or identical, thereby improving the integrity of the final packages. In addition, singulation of packages having similar or identical compositions for the dielectric film and encapsulant may be associated with reduced chipping or delamination between layers.

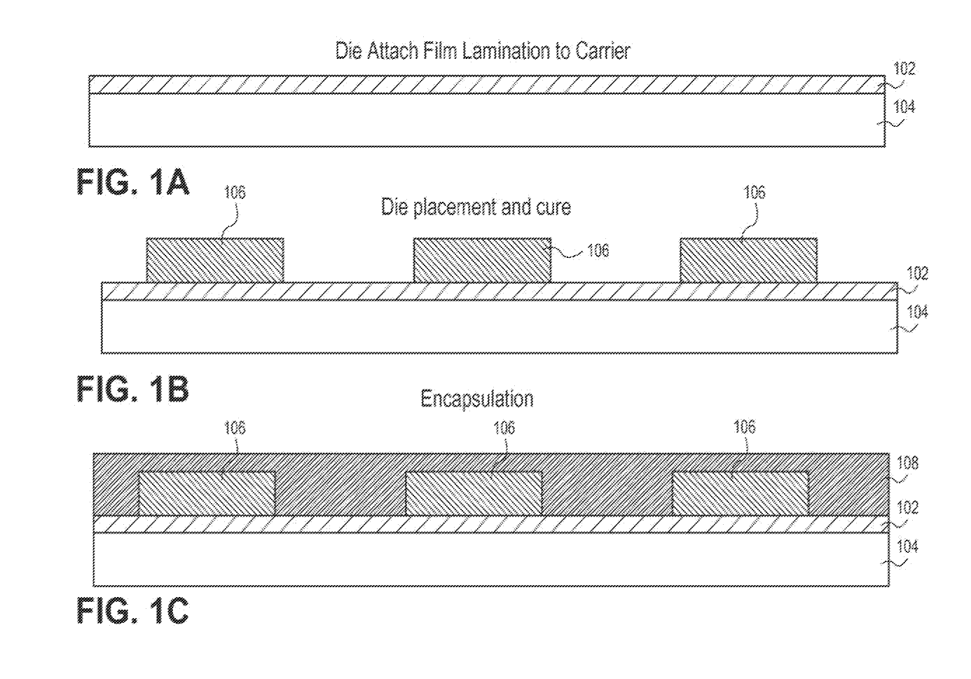

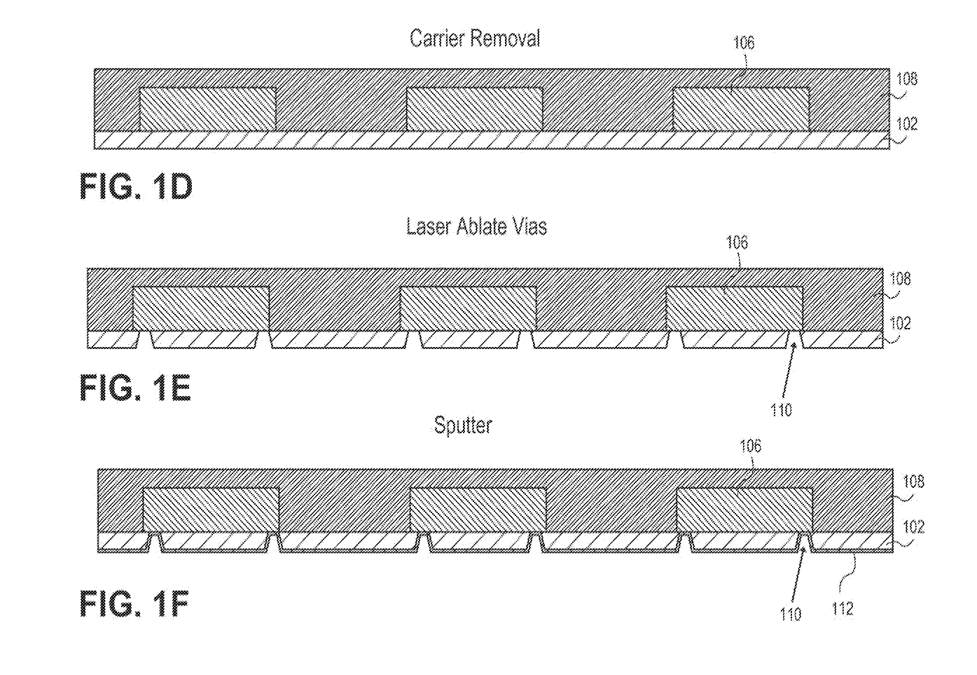

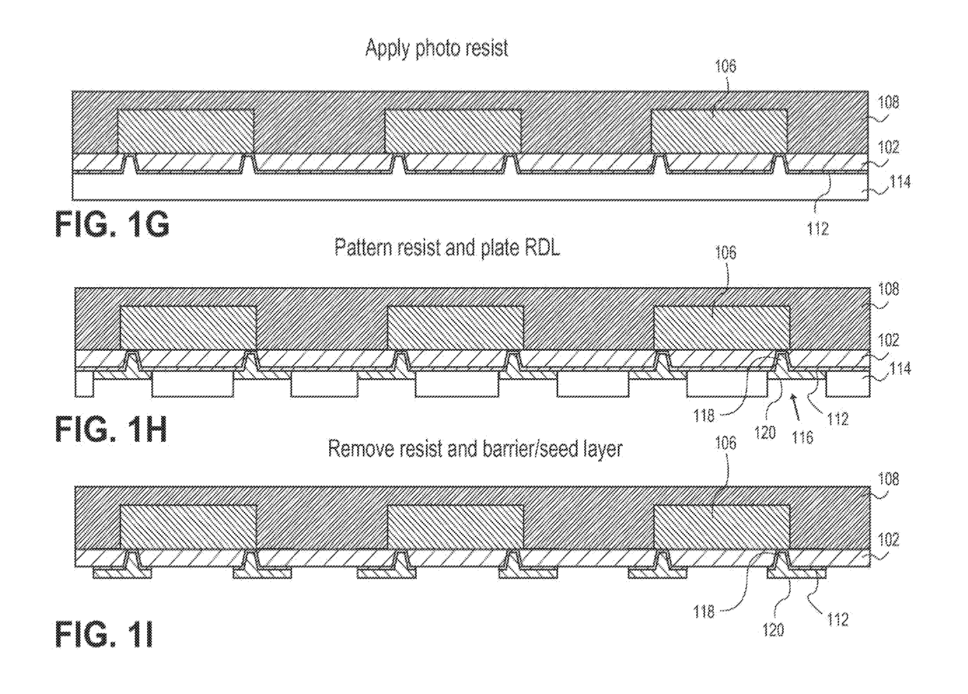

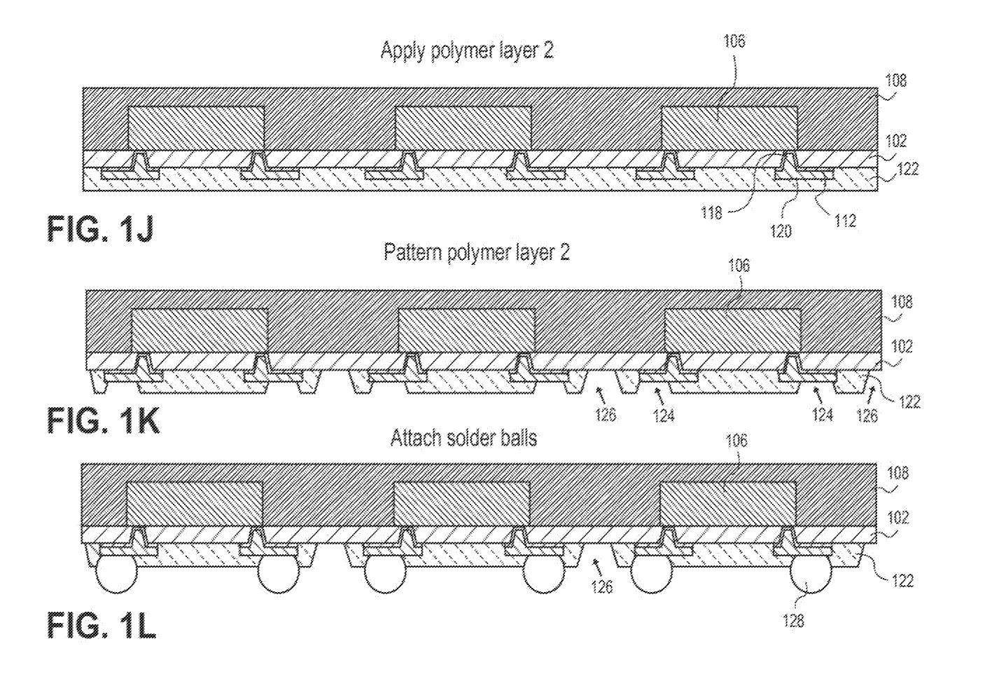

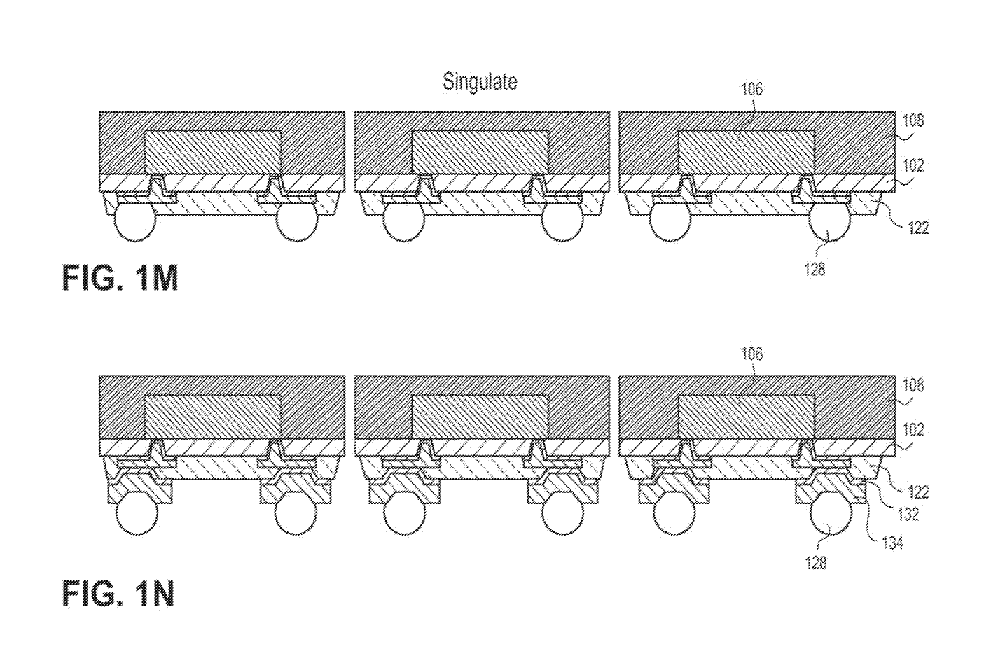

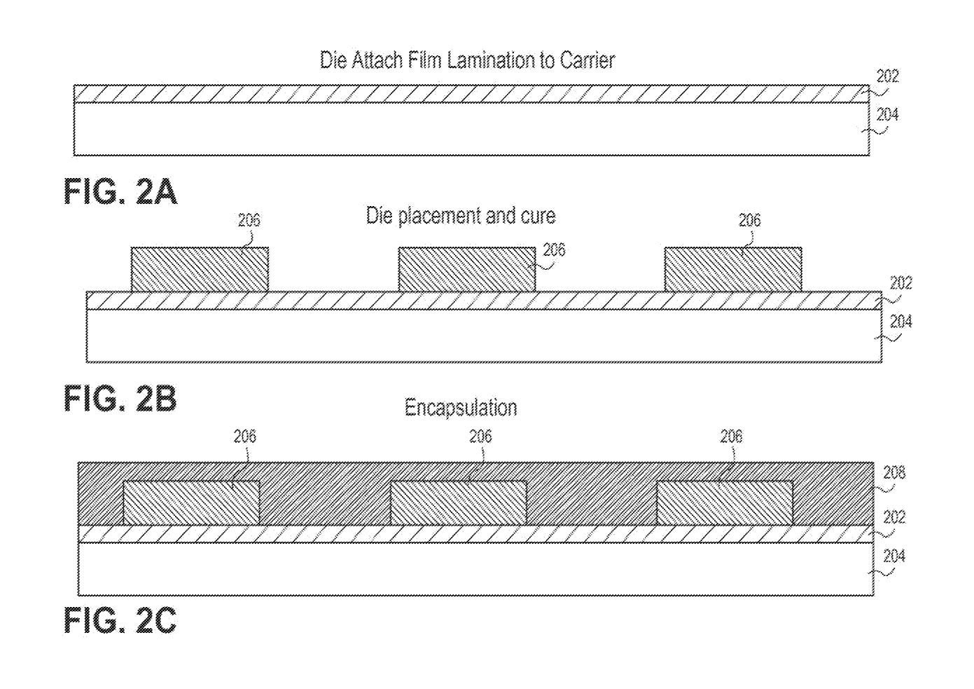

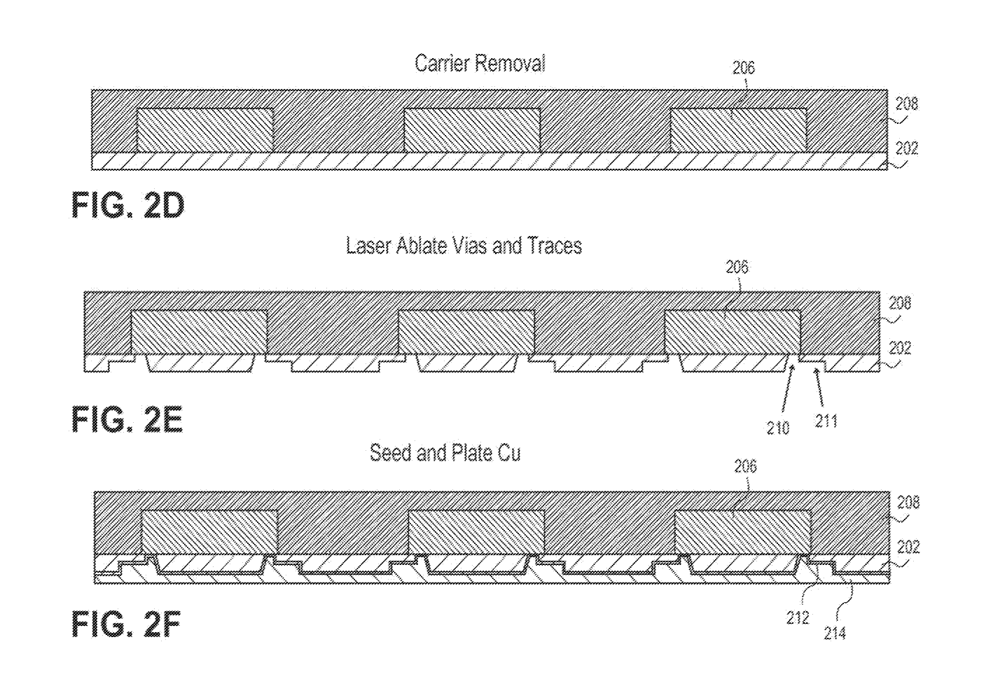

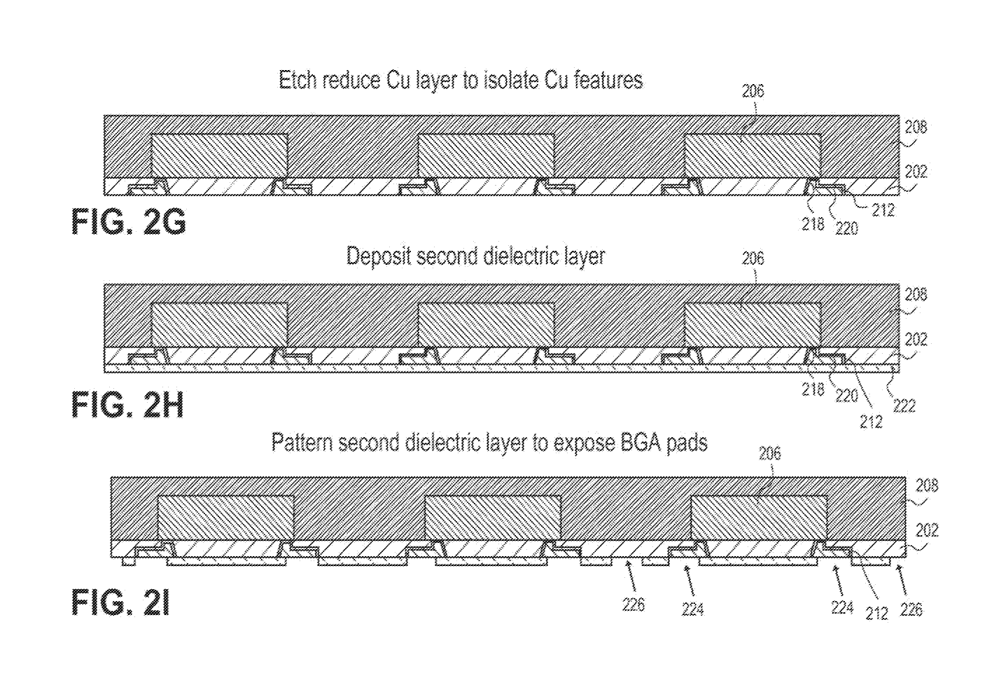

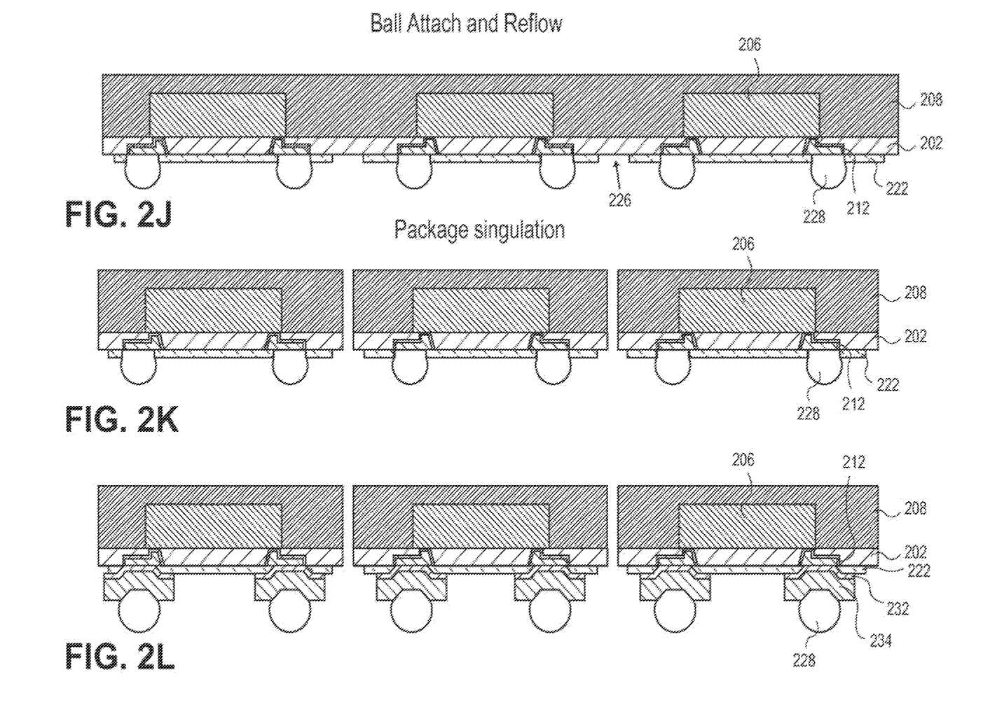

FIGS. 1A-1N and FIGS. 2A-2L illustrate methods for forming a fan-out WLCSP in which a permanent dielectric film is patterned during the formation of alternative build-up structures in accordance with embodiments of the invention. FIGS. 1A-1N illustrate an embodiment in which a redistribution layer (RDL) trace of the build-up structure is formed over the dielectric FIGS. 2A-2L illustrate an embodiment in which a RDL trace of the build-up structure is formed within the dielectric film. Various modifications and changes may be made to the particular build-up structures illustrated including, but not limited to, build-up structures with multiple dielectric layers and device interconnect traces, which may or may not be associated with the RDL traces. Such multi-layer build-up structures can be utilized in both single-die package applications as well as multi-device modules. Accordingly, the specific embodiments illustrated in FIGS. 1A- 1N and FIGS. 2A-2L are to be regarded in an illustrative sense rather than a restrictive sense.

Referring to FIG. 1A, in an embodiment the process begins with attaching a dielectric film 102 to a temporary carrier substrate 104. In an embodiment, the dielectric film 102 is laminated to the temporary carrier substrate 104. Such a laminated dielectric film 1102 may be uniformly applied across the temporary carrier substrate 104 and also be readily releasable from the temporary carrier substrate 104 at a later stage. For example, lamination can be performed by rolling under heat and pressure. Other methods of attaching the dielectric film 102 to the temporary carrier substrate 104 are also contemplated such as spin coating, printing, and spraying.

In an embodiment, the dielectric film 102 is formed of a material such as an epoxy, polyimide or silicone in which the mechanical properties of the material are substantially fully developed by curing. Dielectric film 102 may be formed of a printed circuit board (PCB) prepreg material. For example, dielectric film 102 may be formed of a partially cured, B-stage cured epoxy, and may include additional filler(s). In an embodiment, it is possible to laminate the dielectric film 102 at temperatures significantly below the glass transition temperature (Tg) of the resultant fully cured dielectric film 102. For example, a dielectric film 102 including a B-stage cured epoxy having a resultant film Tg of approximately 140-190° C. can be vacuum laminated at approximately 100-130° C. Dielectric film 102 may be opaque, or alternatively at least partially translucent. Temporary carrier substrate 104 may be formed of a variety of materials such as, but not limited to, steel, glass, and sapphire which are rigid enough not to move during a subsequent molding operation, and releasable from dielectric film 102 after the molding operation. In an embodiment, the dielectric film is 5 to 50 microns thick, and the temporary carrier substrate 104 is approximately 2 mm thick.

Referring to FIG. 1B, a plurality of die units may be placed on a surface of dielectric film 102, for example, by utilizing a pick and place die attach machine, and the dielectric film 102 may be cured to lock the plurality of die units into place on the cured, rigid dielectric film 102, which may be rendered non-photoimageable by the curing process. Curing may be performed during or after placement and may be performed by a variety of method such as thermal, ultraviolet (UV), or microwave curing cycles until the dielectric film 102 is rigid and substantially cross-linked. In an embodiment, dielectric film 102 includes a B-stage epoxy material, and is final cured at temperature sufficient to fully cross-link the material, typically above the resultant Tg of the final cured dielectric film 102. For example, a dielectric film including a B-stage epoxy having a final cured Tg of approximately 140-160° C. may be cured at approximately 170° C. In an embodiment, dielectric film 102 has a final cured Tg greater than or equal to 190° C. In an embodiment, the dielectric film 102 includes greater than 50%, by weight, of a particulate ceramic filler such as silica. In an embodiment, the dielectric film 102 includes 60-90%, by weight, ceramic filler, in an embodiment, the dielectric film 102 may have a CTE of 11-18 ppm/° C. at room temperature, such as approximately 12 ppm/° C. at room temperature. In an embodiment, curing achieves enough adhesion between the dielectric film 102 and plurality of die units 106 to meet first level package reliability metrics such as delamination during moisture sensitivity testing, or mounting to a motherboard or other product.

After curing the dielectric film 102, the plurality of die units 106 on the dielectric film 102 are encapsulated with an encapsulant layer 108 as illustrated in FIG. 1C such that the plurality of die units are encapsulated by the encapsulant layer 108 and dielectric film 102. During encapsulation, the temporary carrier substrate 104 prevents flexing or movement of the cured dielectric film 102, and the cured dielectric film 102 holds the plurality of individual die units in place, thereby improving alignment within the panel or reticulated wafer. As illustrated in FIG. 1C, in an embodiment, the active surfaces of the plurality of die units 106 are substantially flush with the surface of the encapsulant layer 108 on dielectric film 102.

In an embodiment, encapsulation is performed by an overmolding process such as compression molding with a molding compound. The molding compound may be a powder including epoxy resin and filler(s). For example, compression molding may be performed at approximately 170° C. to completely melt a powder epoxy resin included in an encapsulant layer 108 having a final Tg of approximately 140-160° C. In an embodiment, the molding compound includes greater than 50%, by weight, of a particulate ceramic filler such as silica. In an embodiment, the molding compound includes 60-90%, by weight, ceramic filler. In an embodiment, the final cured molding compound may have a CTE of 11-18 ppm/° C. at room temperature, such as approximately 12 ppm/° C. at room temperature. It is also contemplated that overmolding in accordance with embodiments of the invention can be accomplished with other methods such as liquid epoxy molding, transfer molding, screen printing, and injection molding.

In an embodiment, encapsulation is performed by vacuum lamination in which final curing may be performed during or after lamination. Similar to dielectric film 102, encapsulant layer 108 can include a B-stage cured material and additional file(s). In an embodiment, dielectric film 102 and encapsulant layer 108 may be formed of identical materials or materials having similar physical properties. Lamination of encapsulant layer 108 may allow for the use of a printed circuit board (PCB) prepreg material sheet, and may be relatively lover cost than injection molding materials. Lamination performed under heat and vacuum can take advantage of the fusible (compliant) nature of a B-stage cured material to encapsulate the plurality of die units 106. In addition, because an encapsulant layer 108 component is B-stage cured it is possible to encapsulate at a temperature well below the final cured Tg of the encapsulant layer 108, and to perform final curing after the encapsulant layer 108 has been formed/shaped around the plurality of die units 106. In an embodiment, lamination may include placing a semi-cured encapsulant film (e.g. including B-s age cured epoxy) over the plurality of die units 106 on the cured dielectric film 102 and applying heat and pressure under vacuum to the semi-cured encapsulant film to form/shape encapsulant layer 108. for example, lamination may be performed at approximately 130° C. and 30 kg/cm² for an encapsulant layer 108 having a final cured Tg of approximately 140-215° C. In an embodiment, laminated encapsulant layer 108 is formed of a material having a final cured Tg greater than or equal to 190° C. In an embodiment, the lamination film includes greater than 50%, by weight, such as 60-90% of a particulate ceramic filler such as silica. In an embodiment, the final cured laminated encapsulant layer 108 may have a CTE of 11-18 ppm/° C. at room temperature, such as approximately 12 ppm/° C. at room temperature. Final curing may subsequently be performed after lamination at a temperature sufficient to fully cross-link the encapsulant material, typically above the resultant Tg of the final cured encapsulant layer 108.

The temporary carrier substrate 104 may then be released from the dielectric film 102 as illustrated in FIG. 1D, leaving the dielectric film 102 attached to what is commonly referred to as a panel or reconstituted wafer including the plurality of die units 106 and encapsulant 108. Releasing may be accomplished by a variety of techniques such as UV irradiation, peeling, laser release, etching, and grinding.

Referring to FIG. 1E, first level via holes 110 may then be formed in dielectric film 102 utilizing a mask-less patterning technique such as laser ablation. In an embodiment, the formation of first level via holes 110 exposes a bond pad (not illustrated) formed on die unit 106. First level via holes 110 may have a diameter of approximately 25 to 50 microns, for example. In one embodiment, dielectric film 102 is at least partially translucent. In accordance with embodiments of the present invention, an optical inspection operation may optionally be performed to measure the true location of any or all die units 106 after removal of the temporary carrier substrate 104 in FIG. 1D and prior to the formation of the first level via holes 110 illustrated in FIG. 1E. If the true location does not match a nominal, reference location, then the x-y position and/or orientation of the first level via holes 110, or any of the other features in the build-up structure, may be adjusted for any of the individual die units as described in co-pending U.S. patent application Ser. No. 12/876,915, incorporated herein by reference.

A barrier and/or seed layer 112 may then be formed over the entire surface and within first level via holes 110 as illustrated in FIG. 1F. For example, layer 112 may include a Ti, Ti/W or Ti/TiN bi-layer barrier layer of approximately 500 to 1,500 angstroms thick, and a copper seed layer of approximately 1,500 to 4,000 angstroms thick. In an embodiment layer 112 can be formed by sputtering.

Referring to FIG. 1G, a photoresist layer 114 may then be formed over layer 112 by a suitable method such as laminating or spin coating. Photoresist layer 114 may then be patterned to form RDL trace pattern openings 116 as illustrated in FIG. 1H. Plating may then follow to fill the openings 110, 116 with the first level via metal 118 and redistribution layer (RDL) trace 120, respectively which may be in electrical communication with the active surface of the die unit 106. In an embodiment, the first level via metal 118 and RDL trace 120 are copper. For example, the plated layer may be greater than or equal to 2 microns thick. Patterned photoresist 114 and underlying portions of barrier/seed layer 112 are then removed as illustrated in FIG. 11. Removal of barrier/seed layer 112 may also slightly reduce the thickness of the plated layer.

Referring to FIG. 1J, a second polymer layer 122 is formed over the patterned dielectric film 102 and RDL traces 120. In an embodiment, the second polymer layer 122 is formed from a photoimageable material such as polyimide, benzocylobutene (BCB), polybenzoxazole (PBO), etc. The second polymer layer 122 may then be patterned to form openings 124 to expose RDL traces 120 as illustrated FIG. 1K. Openings 126 may also be formed to expose portions of dielectric film 102 to assist in singulation. Patterning of openings 124, 126 may be performed utilizing suitable photolithographic techniques. Layer 122 is not limited to polymer materials, and may be formed of other materials having suitable dielectric and sealing properties.

As illustrated in FIG. 1L, solder balls 128 may then be applied over the exposed portions of the RDL traces 120. Referring to FIG. 1M, individual packages may th be singulated. As illustrated in FIG. 1M, singulation may include cutting of only the dielectric film 102 and encapsulant 108, where lateral edges of the second polymer layer 122 do not extend to, and are not flush with the lateral edges of dielectric film 102 and encapsulant 108 for the individual packages. Such a structure may be associated with reduced chipping and/or delamination between layers during singulation. In an embodiment where encapsulant 108 and die bonding film 102 are both formed from an epoxy material, and second polymer layer 122 is formed of a polyimide, cutting during singulation is only required to be made through layers of similar composition, characteristics and therefore chipping and/or delamination is reduced.

It is understood that additional layers may be formed such as ball grid array capture pads prior to applying solder balls 128. For example, as illustrated in FIG. 1N the processes of FIGS. 1G-1H may be repeated to form barrier/seed layer 132 and ball grid array capture pads 134 prior to attaching solder balls 128.

Referring to FIGS. 2A-2L, in a second embodiment, an alternative WLCSP build-up structure can be formed. As illustrated in FIGS. 2A-2D, a dielectric film 202 may be laminated to a temporary carrier substrate. A plurality of die units 206 are attached to dielectric film 202. Dielectric film 202 is then cured to lock the plurality of die units 206 into place. The plurality of die units 206 are then overmolded or laminated with an encapsulant 208. The temporary carrier substrate 204 is then removed.

Referring to FIG. 2E, first level via holes 210 and RDL, trace patterns 211 may be formed in the dielectric film 202 utilizing a mask-less patterning technique such as laser ablation. In one embodiment, dielectric film 202 is at least partially translucent. In accordance with embodiments of the present invention, an optical inspection operation may optionally be performed to measure the true location of any or all die units 206 after removal of the temporary carrier substrate 204 in FIG. 2D and prior to the formation of the first level via holes 210 and RDL trace pattern 211 illustrated in FIG. 1F. If the true location does not match a nominal, reference location, then the x-y position and/or orientation of the first level is holes 210, or any of the other features in the build-up structure, may be adjusted for any of the individual die units as described in co-pending U.S. patent application Ser. No. 12/876,915, incorporated herein by reference.

A barrier and/or seed layer 212 may be formed following by plating of a metallic layer 214 such as copper, which may then be etched back to isolate first level vias 218 and RDL traces 220 within the dielectric film 202 as illustrated in FIGS. 2F-2G. A second polymer layer 222 may then be formed and patterned utilizing suitable lithographic techniques to form openings 224, 226 as illustrated in FIGS. 2H-2I. Solder balls 228 may be applied within openings 224 over the exposed portions of the RDL trace 220, while openings 226 may assist in singulation of the individual packages as illustrated in FIGS. 2J-2K. In an embodiment illustrated in FIG. 2L a barrier/seed layer 232 and ball grid array capture pad 234 may be formed similarly as described with regard to FIG. 1N.

In the foregoing specification, various embodiments of the invention have been described. It will, however, be evident that various modifications and changes may be made thereto without departing from the broader spirit and scope of the invention as set forth in the appended claims. For example, various structural alternatives and processes have been described for CSP build-up structures. It is contemplated that a variety of build-up structures and processes could be applied after formation of the first level via in the dielectric film utilizing a mask-less patterning technique such as laser ablation. The specification and drawings are, accordingly, to be regarded in an illustrative sense rather than a restrictive sense.

1. A package comprising:
a non-photoirnageable dielectric film;
an active surface of a die unit attached to the dielectric film;
a redistribution layer (RDL) formed over the dielectric film and configured to be in electrical communication with the active surface of the die unit; and
an encapsulant layer comprising epoxy that encapsulates the die unit on the dielectric film;
wherein lateral edges of the encapsulant layer and the dielectric film are substantially flush.

2. The package of claim 1, further comprising:
a polymer layer disposed over the dielectric film; and
an opening formed in the polymer layer that exposes a RDL.

3. The package of claim 1, wherein the dielectric film and the encapsulant layer both comprise greater than approximately 50% of a ceramic or silica filler, by weight.

4. The package of claim 1, wherein the dielectric film and the encapsulant layer both have a glass transition temperature (Tg) greater than or equal to 140 degrees C.

5. The package of claim 1, wherein the encapsulant layer is disposed on a backside and four side surfaces of the die unit.

6. The package of claim 1, wherein the active surface of the die unit is substantially flush with a surface of the encapsulant layer on the dielectric film.

7. The package of claim 1, wherein the dielectric film comprises a thickness in a range of 5-50 micrometers.

8. The package of claim 1, further comprising:
a via formed through the dielectric film; and
a conductive material disposed within the via that is electrically coupled to the active surface of the die unit.

9. A package comprising:
a non-photoimageable dielectric film;
an active surface of a die unit attached to the dielectric film; and
an encapsulant layer comprising epoxy that encapsulates the die unit on the dielectric film;
wherein the active surface of the die unit is substantially flush with a surface of the encapsulant layer on the dielectric film.

10. The package of claim 9, wherein the encapsulant layer is disposed on a backside and four side surfaces of the die unit.

11. The package of claim 9, wherein lateral edges of the encapsulant/capsulant layer and the dielectric film are substantially flush.

12. The package of claim 9, wherein the dielectric film and the encapsulant layer are formed of identical materials.

13. The package of claim 9, wherein the dielectric film and the encapsulant layer comprise a CTE of 11-18 ppm/° C. at room temperature.

14. The package of claim 9, wherein the dielectric film and the encapsulant layer both comprise greater than approximately 50% of a ceramic or silica filler, by weight.

15. The package of claim 9, wherein the dielectric film comprises a B-stage cured epoxy.

16. A package comprising:
a dielectric film;
an active surface of a die unit attached to the dielectric film; and
an encapsulant layer comprising epoxy that encapsulates the die unit on the dielectric film;
wherein the dielectric film and the encapsulant layer both comprise greater than approximately 50% of a ceramic or silica filler, by weight.

17. The package of claim 16, further comprising:
a polymer layer disposed over the dielectric film; and
an opening formed in the polymer layer that exposes a redistribution layer (RDI) formed over the dielectric film and configured to be in electrical communication with the active surface of the die unit.

18. The package of claim 16, wherein the dielectric film and the encapsulant layer both have a glass transition temperature (Tg) greater than or equal to 140 degrees C.

19. The package of claim 16, wherein the dielectric film and the encapsulant layer comprise a CTE of 11-18 ppm/° C. at room temperature.

20. The package of claim 17, wherein the active surface of the die unit is substantially flush with a surface of the encapsulant layer on the dielectric film.

21. The package of claim 17, wherein lateral edges of the encapsulant layer and the dielectric film are substantially flush.
